(19) United States
(12) Patent Application Publication
(10) Pub. No.: US 2018/0228047 A1
(43) Pub. Date: Aug. 9, 2018

(54) ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventors: Takuya Ota, Yokkaichi, Mie (JP); Shigeki Yamane, Yokkaichi, Mie (JP); Hirotoshi Maeda, Yokkaichi, Mie (JP); Toshiyuki Tsuchida, Yokkaichi, Mie (JP); Yoshihiro Tozawa, Yokkaichi, Mie (JP)

(21) Appl. No.: 15/749,623

(22) PCT Filed: Jul. 26, 2016
(86) PCT No.: PCT/JP2016/071802

§ 371 Date: Feb. 1, 2018

(30) Foreign Application Priority Data
Aug. 3, 2015 (JP) 2015-153215

(51) Int. Cl. H05K 7/14; H05K 7/20; H02G 3/08; H02G 3/16; H01R 13/66

(52) U.S. Cl. CPC H05K 7/1432; H05K 7/2039; H01R 13/6658; H02G 3/16; H02G 3/086

(57) ABSTRACT

Provided is an electrical junction box including: a circuit board that has a mounting surface on which an electronic component is mounted; and a frame in which the circuit board is accommodated. The frame is provided with a board covering portion that covers a part of the electronic component on the mounting surface side, and the board covering portion is provided with a retaining portion that retains the electronic component. Furthermore, it is also possible to provide an outer case that covers the board covering portion from a side opposite to the side on which the circuit board is arranged while overlapping the board covering portion.

### CROSS-REFERENCE TO RELATED APPLICATIONS

This application is the U.S. national stage of PCT/JP2016/071802 filed Jul. 26, 2016, which claims priority of Japanese Patent Application No. JP 2015-153215 filed Aug. 3, 2015.

### TECHNICAL FIELD

The technology disclosed in the present description relates to an electrical junction box.

### BACKGROUND

Conventionally, as devices for activating and deactivating onboard electrical components in a vehicle, electrical junction boxes in which a circuit board with various electronic components mounted thereon is accommodated in a case are known.

The electronic components that are mounted on the board of such an electrical junction box include, for example, relatively large electronic components such as coils. The large electronic components are fixed by separate fixing means because, if terminals of the large electronic components are connected to a conductive circuit on the board only by soldering, then there is the risk that the solder may crack due to vibration while the vehicle is moving, for example. Specifically, an adhesive is applied to the peripheries of the bottoms of the electronic components to fix them to the board, or screws are fastened, or blade springs or the like are used to mechanically fix the electronic components to the board.

However, in the configuration using an adhesive, it is necessary to provide a relatively large application region that does not include other components so that the adhesive does not affect the other components. Furthermore, when screws are fastened or blade springs or the like are used to perform mechanical fixation, a region for fixing the screws or blade springs to the board is additionally needed. Such fixing means are causes of increasing density of the circuit board, and thus preventing downsizing of the electrical junction box.

The technique disclosed in the present description was made in view of the above-described circumstances, and it is an object thereof to downsize a circuit board and an electrical junction box.

### SUMMARY

The technique disclosed in the present description relates to an electrical junction box including: a circuit board that has a mounting surface on which an electronic component is mounted; and a frame body in which the circuit board is accommodated, wherein the frame body includes a board covering portion that covers at least a part of the electronic component on the mounting surface side, and the board covering portion is provided with a retaining portion that retains the electronic component.

According to the above-described configuration, since the electronic component is retained by the retaining portion provided in the board covering portion of the frame body, there is no need to additionally set a region in which a fixing means for fixing the electronic component to the circuit board is to be provided. Accordingly, it is possible to downsize the circuit board, and thus the electrical junction box.

Meanwhile, when an electronic component is arranged on a circuit board during manufacturing of an electrical junction box, it is often the case where a positioning jig or dedicated device is used to arrange the electronic component with accuracy. However, according to the above-described configuration, the retaining portion of the board covering portion that constitutes the electrical junction box has the same function as that of a positioning jig, that is, the retaining portion can be used to position the electronic component with respect to the board, and thus no positioning jig or dedicated device is needed. Accordingly, it is possible to reduce the manufacturing cost, and simplify a manufacturing method.

The retaining portion may be a retaining wall that extends along an outer surface of the electronic component. Alternatively, the retaining portion may be a retaining hole that passes through the covering portion.

Furthermore, if the retaining portion is a retaining hole, then the electrical junction box may further include an outer case that covers the board covering portion from a side opposite to the side on which the circuit board is arranged while overlapping the board covering portion. According to this configuration, even if an electronic component that is exposed from the retaining hole is attempted to move in a direction perpendicular to the mounting surface, the outer case restricts the electronic component from moving, and thus it is possible to retain the electronic component on the circuit board more reliably.

Furthermore, the electronic component and the outer case may be adhered to each other by a thermally conductive adhesive. According to this configuration, heat generated in the electronic component can immediately be transmitted to the outer case, and can be discharged to the outside, and thus an increase in the temperature of the electrical junction box is suppressed.

Furthermore, a configuration is also possible in which the retaining portion may be provided with a biasing means for biasing the electronic component to the mounting surface side. According to this configuration, it is possible to retain the electronic component on the circuit board much more reliably.

Specifically, the biasing means may be a spring member such as a blade spring or a coil spring.

Furthermore, the electronic component may be fixed to the retaining portion with an adhesive.

Furthermore, a retaining portion into which a plurality of electronic components are together fitted may be provided. According to this configuration, the plurality of electronic components are fixed while being lined up without a gap therebetween, and thus it is possible to further downsize the entire electrical junction box.

### Advantageous Effects of Invention

According to the technique disclosed in the present description, it is possible to downsize a circuit board and an electrical junction box.

### BRIEF DESCRIPTION OF DRAWINGS

FIG. 1 is an exploded perspective view of an electrical junction box according to one embodiment.

FIG. 2 is a perspective view of the electrical junction box according to one embodiment.

FIG. 3 is a plan view of the electrical junction box according to one embodiment.

FIG. 4 is a cross-sectional view taken along a line A-A in FIG. 3.

FIG. 5 is a front view of a coil.

FIG. 6 is a side view of the coil.

FIG. 7 is a plan view of the coil.

FIG. 8 is a bottom view of the coil.

FIG. 9 is a plan view of a heatsink.

FIG. 10 is a plan view illustrating a positional relationship between a circuit board and the heatsink.

FIG. 11 is a plan view of a case.

FIG. 12 is a side view of the case.

FIG. 13 is a front view of the case.

FIG. 14 is a bottom view of the case.

FIG. 15 is a bottom-side perspective view illustrating a state in which coils are arranged in the case.

FIG. 16 is a bottom-side perspective view illustrating a state in which the coils and the board are arranged in the case.

FIG. 17 is a bottom view illustrating the state in which the coils and the board are arranged in the case.

FIG. 18 is a plan view illustrating the state in which the coils and the board are arranged in the case.

FIG. 19 is a cross-sectional view taken along a line B-B in FIG. 18.

FIG. 20 is a cross-sectional view illustrating a retaining portion according to another embodiment.

FIG. 21 is a cross-sectional view illustrating a retaining portion according to another embodiment.

FIG. 22 is a cross-sectional view illustrating a method for manufacturing an electrical junction box according to another embodiment.

FIG. 23 is a cross-sectional view illustrating a coil fixing structure according to another embodiment.

FIG. 24 is a cross-sectional view illustrating a coil fixing structure according to another embodiment.

FIG. 25 is a cross-sectional view illustrating a coil fixing structure according to another embodiment.

FIG. 26 is a cross-sectional view illustrating a retaining portion according to another embodiment.

FIG. 27 is a cross-sectional view illustrating a coil fixing structure according to another embodiment.

### DETAILED DESCRIPTION OF PREFERRED EMBODIMENTS

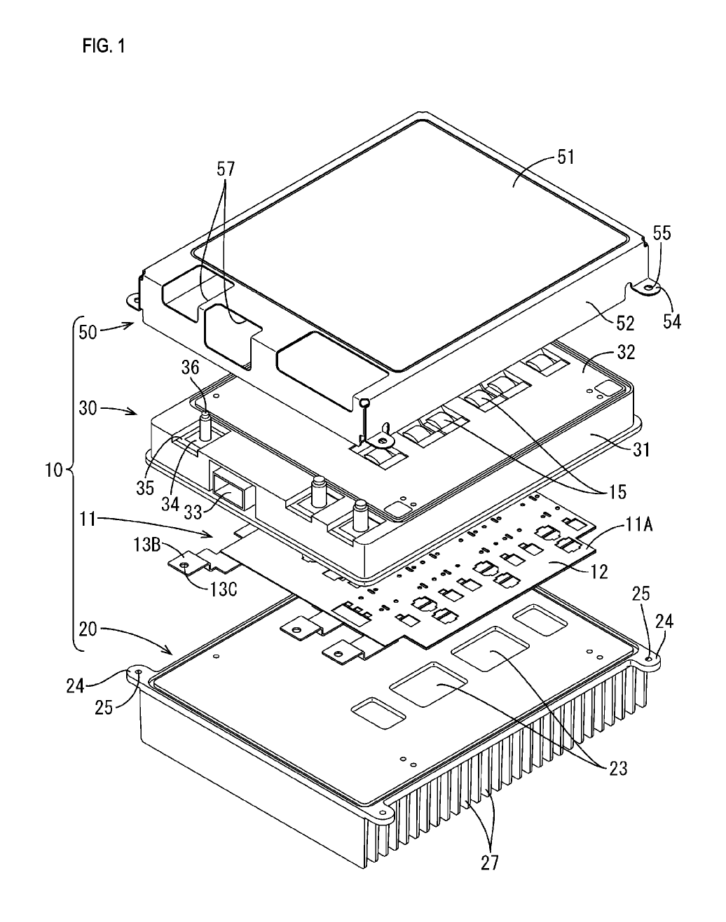

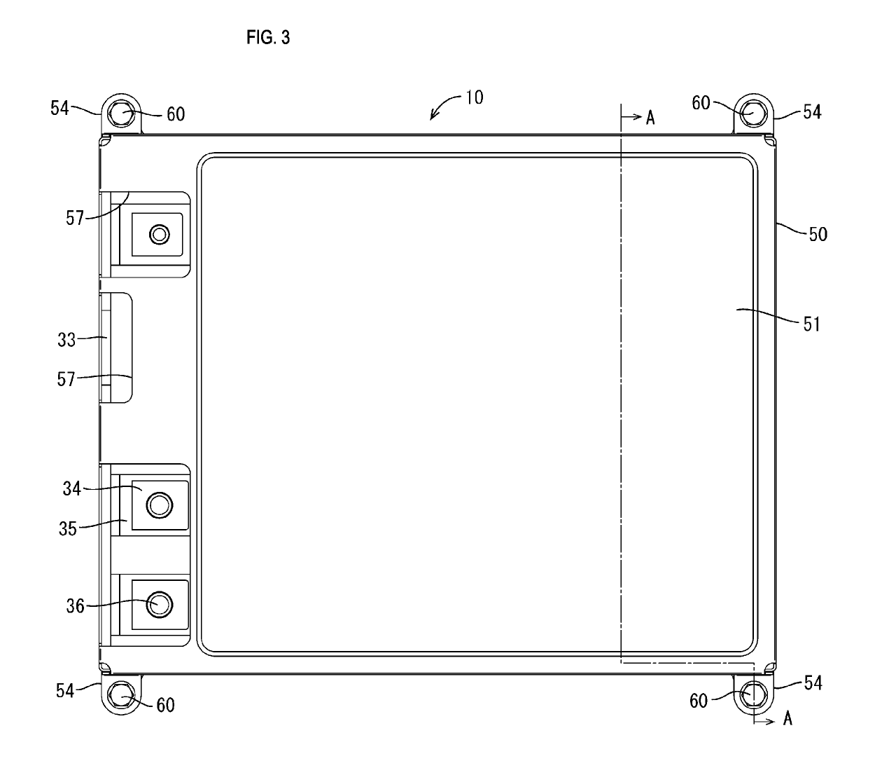

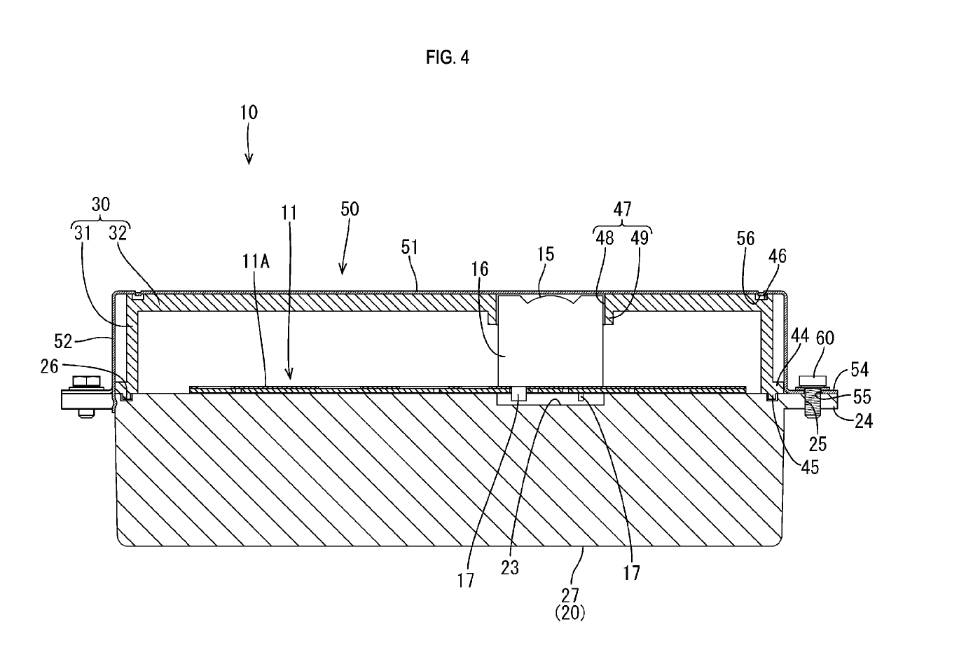

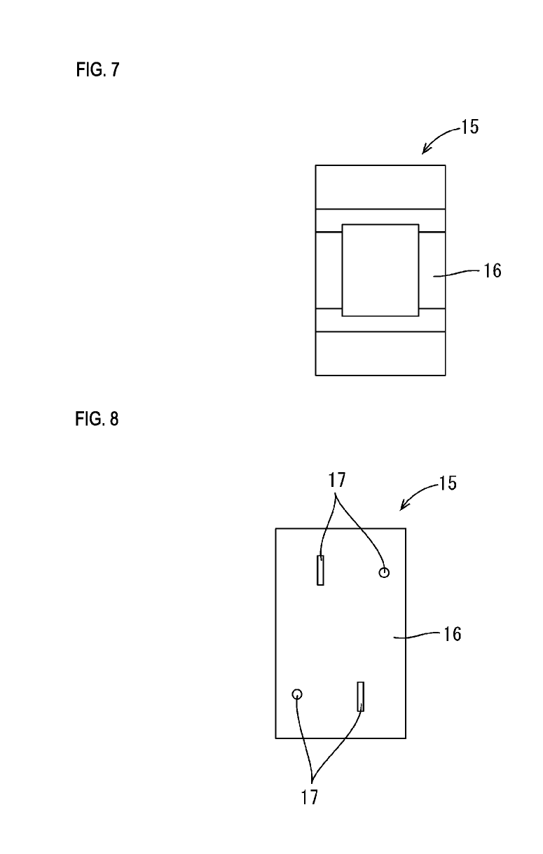

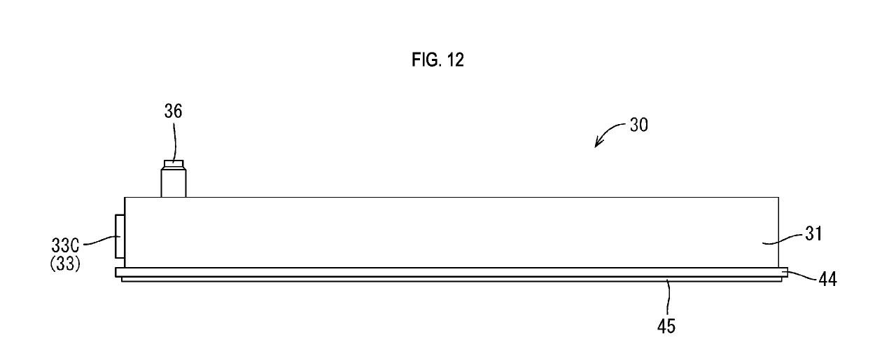

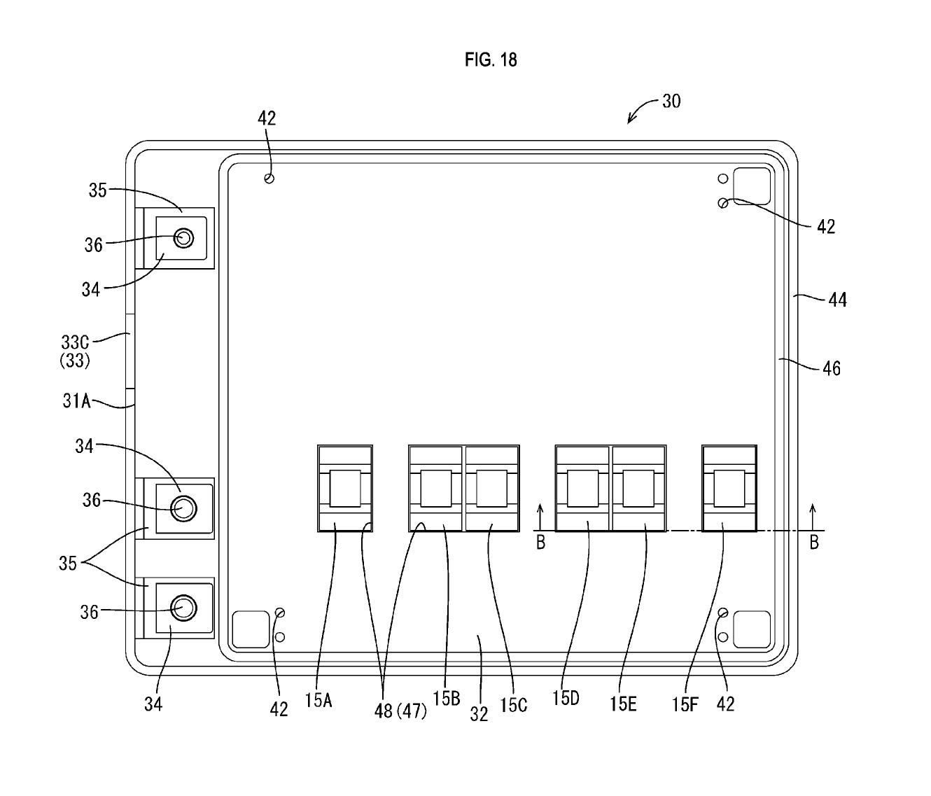

One embodiment will be described with reference to FIGS. 1 to 19. An electrical junction box 10 according to the present embodiment is arranged between a power source such as a battery, and an onboard electrical component such as a lamp or a motor, and is configured to supply and interrupt electric power from the power source to the onboard electrical component. In the following description, “top” or “upper” refers to the upper side of FIG. 4, and “back” or “lower” refers to the lower side. Furthermore, “frontward” (front side) refers to the left side of FIG. 3, “rearward” (rear side) refers to the right side, and “left-right direction” refers to the up-down direction of FIG. 3.

As shown in FIGS. 1 and 4, the electrical junction box 10 is provided with: a circuit board 11; a heatsink 20 disposed on the back side (the lower side of FIG. 4) of the circuit board 11; a case 30 in which the circuit board 11 is accommodated; and a shield cover 50 that covers the case 30 from the side opposite to the heatsink 20 (the upper side of FIGS. 1 and 4).

### Circuit Board 11

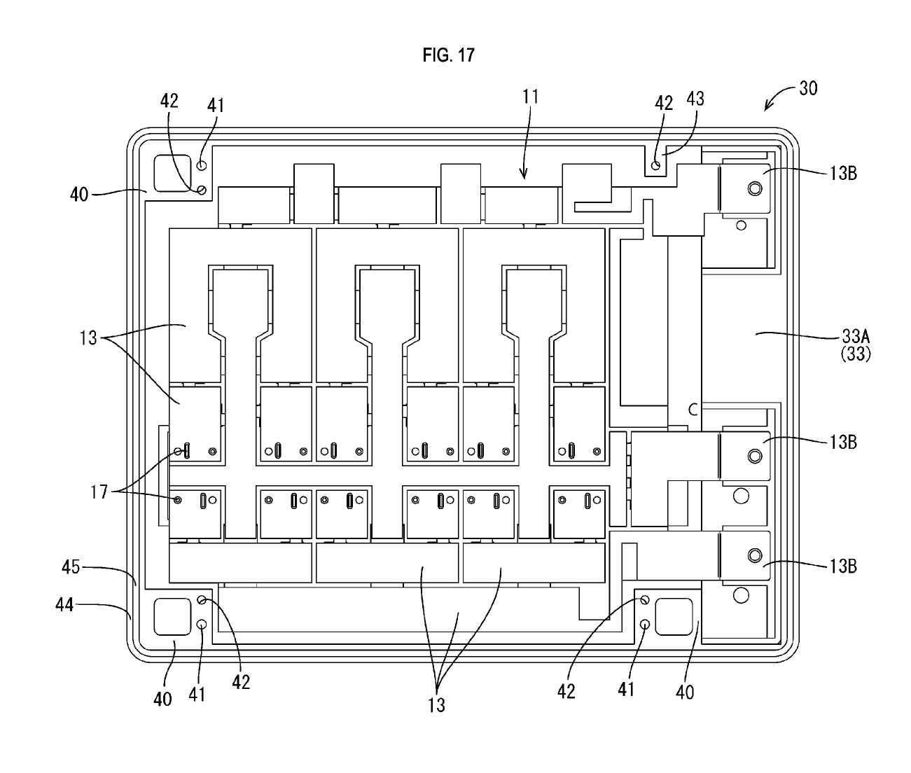

The circuit board 11 is obtained such that a printed wiring board 12 is prepared by forming a not-shown conductive circuit on an insulation board using printed wiring, a plurality of busbars 13 are laid out and adhered in a predetermined pattern to the back side of the printed wiring board 12 (see FIGS. 16 and 17), and electronic components are mounted at predetermined positions on the conductive circuit and the busbars 13. Hereinafter, “mounting surface 11A” refers to the surface (top surface) of the circuit board 11 on which the electronic components are mounted.

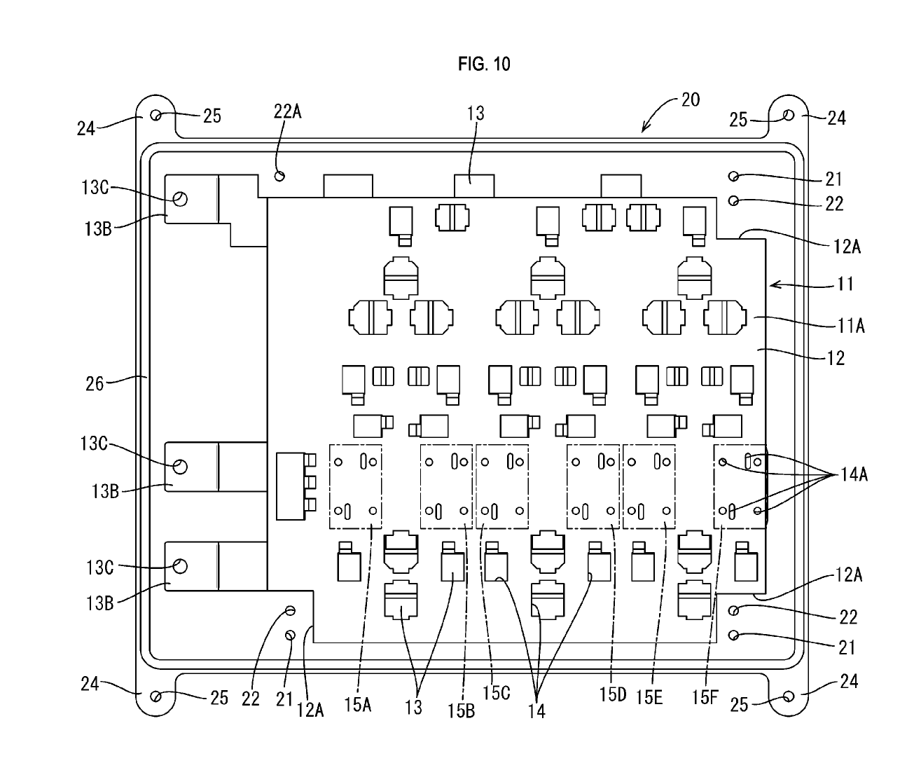

As shown in FIG. 10, the printed wiring board 12 is substantially rectangular with, at three of its four corners, cutout portions 12A that are cut out in a rectangular shape, and is provided with a plurality of connection through holes 14 at predetermined positions. These connection through holes 14 are used to mount electronic components on the busbars 13, and the electronic components are connected to the surfaces of the busbars 13 that are exposed from the connection through holes 14, or the lands of the not-shown conductive circuit using a well-known method such as soldering, for example.

Note that in the present embodiment, only relatively large coils 15 are shown out of the plurality of electronic components, and illustration of other electronic components is omitted. The coils 15 are arranged at the positions of FIG. 10 that are denoted by dashed-dotted lines.

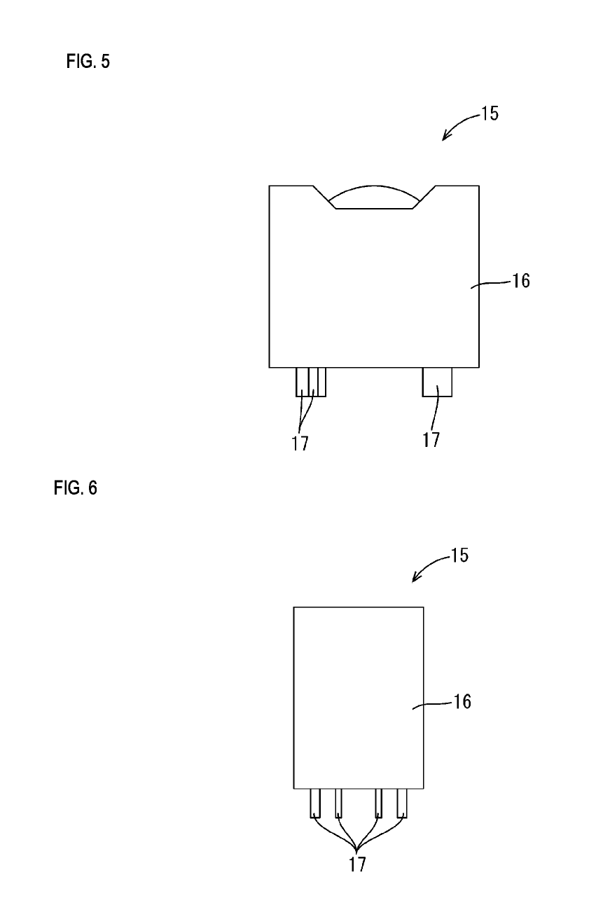

The coils 15 (examples of an electronic component) used in the present embodiment are lead-type coils 15, and have, as shown in FIGS. 5 to 8, a substantially cuboid main portion 16, and two pin-shaped lead terminals 17 and two plate-shaped lead terminals 17 that alternately project downward from the bottom of the main portion 16. In the present embodiment, six coils 15 (hereinafter, referred to as “coils 15A, 15B, 15C, 15D, 15E, and 15F” when they are individually described) are arranged on the printed wiring board 12 in a line in the front-rear direction in the same orientation (see FIG. 10).

The printed wiring board 12 is provided with, in the portions on which the coils 15 are mounted, coil connecting through holes 14A through which the lead terminals 17 of the coils 15 are passed. Similarly, the busbars 13 are provided with, at positions that overlap the coil connecting through holes 14A, busbar-side through holes 13A through which the lead terminals 17 of the coils 15 are passed.

Furthermore, three external connection busbars 13B for connecting to external terminals project from the front side edge (on the left side of FIG. 10) of the printed wiring board 12, and their front end portions are bent in a crank shape. These front end portions are each provided with a bolt hole 13C through which a connection bolt (not shown) is passed.

### Heatsink 20

The heatsink 20 is disposed on the lower surface side of the circuit board 11. The heatsink 20 is a heat discharge member made of a metal material such as, for example, aluminum or an aluminum alloy that is excellent in thermal conductivity, and has the function to discharge heat generated by the circuit board 11.

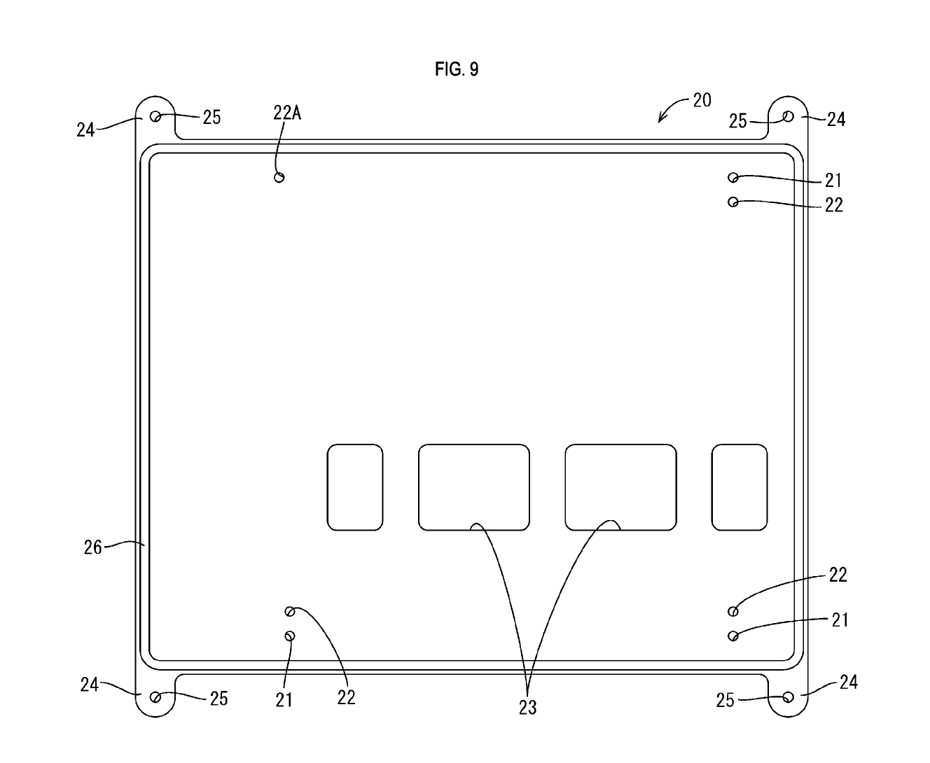

The upper surface of the heatsink 20 is substantially flat plate shaped, and is provided with, in the regions in which the above-described coils 15 are arranged, escape recesses 23 that are recessed downward from the upper surface and can accommodate the lead terminals 17 of the coils 15, as shown in FIG. 9.

As shown in FIG. 10, the upper surface of the heatsink 20 is provided with, in the vicinity of the regions in which the cutout portions 12A of the printed wiring board 12 are arranged, pairs of a heatsink-side positioning hole 21 for positioning the later-described case 30 with respect to the heatsink 20 and a heatsink-side first fixation hole 22 for fixing the case 30 to the heatsink 20, the holes being lined up in the left-right direction (up-down direction of FIG. 10). Furthermore, in the vicinity of the region in which the corner of the printed wiring board 12 without a cutout portion 12A is arranged, only a heatsink-side first fixation hole 22 is provided (hereinafter, this heatsink-side first fixation hole is denoted by “22A”).

The heatsink-side positioning holes 21 and the heatsink-side first fixation holes 22 (four holes in total) that are located on the rear side (on the right side of FIG. 10) are all arranged on a straight line at the same position with respect to the front-rear direction, whereas the heatsink-side positioning hole 21 and the heatsink-side first fixation holes 22 and 22A (three holes in total) that are arranged on the front side (on the left side of FIG. 10) are arranged such that only the heatsink-side first fixation hole 22A provided alone is deviated in the front-rear direction from the positions of the remaining holes.

More specifically, if the case 30 is attached to the heatsink 20 in a different orientation from the proper one, then this configuration prevents a case-side positioning portion 41 from being fitted into the heatsink-side first fixation hole 22A by mistake, and thus makes it possible to detect whether or not the case 30 is attached to the heatsink 20 in the proper orientation.

Furthermore, the upper surface of the heatsink 20 is provided with, at both ends of its long sides extending in the front-rear direction (left-right direction of FIGS. 9 and 10), heatsink-side extension portions 24 that extend in the left-right direction (in the direction in which the short sides extend), and the heatsink-side extension portions 24 are each provided with a heatsink-side second fixation hole 25 for fixing the later-described shield cover 50 thereto, the heatsink-side second fixation hole 25 passing through the heatsink-side extension portion 24.

Furthermore, the heatsink 20 is provided with, in the vicinity of the edge portion of its upper surface, a heatsink-side grove 26 that is recessed downward from the upper surface, and extends annularly along the edge portion. A case-side rib 45 of the later-described case 30 is configured to be fitted into the heatsink-side grove 26.

Moreover, the lower surface of the heatsink 20 is provided with a large number of plate-shaped fins 27 that extend downward (see FIG. 1).

Note that, although not shown, an insulation sheet for ensuring insulation between the heatsink 20 and the circuit board 11 (busbars 13) is laid on the upper surface of the heatsink 20. The insulation sheet is adhesive and can be fixed to the busbars 13 and the heatsink 20. Note that the insulation sheet has, at the positions that correspond to the escape recesses 23, escape holes (not shown) that pass through the insulation sheet.

### Case 30

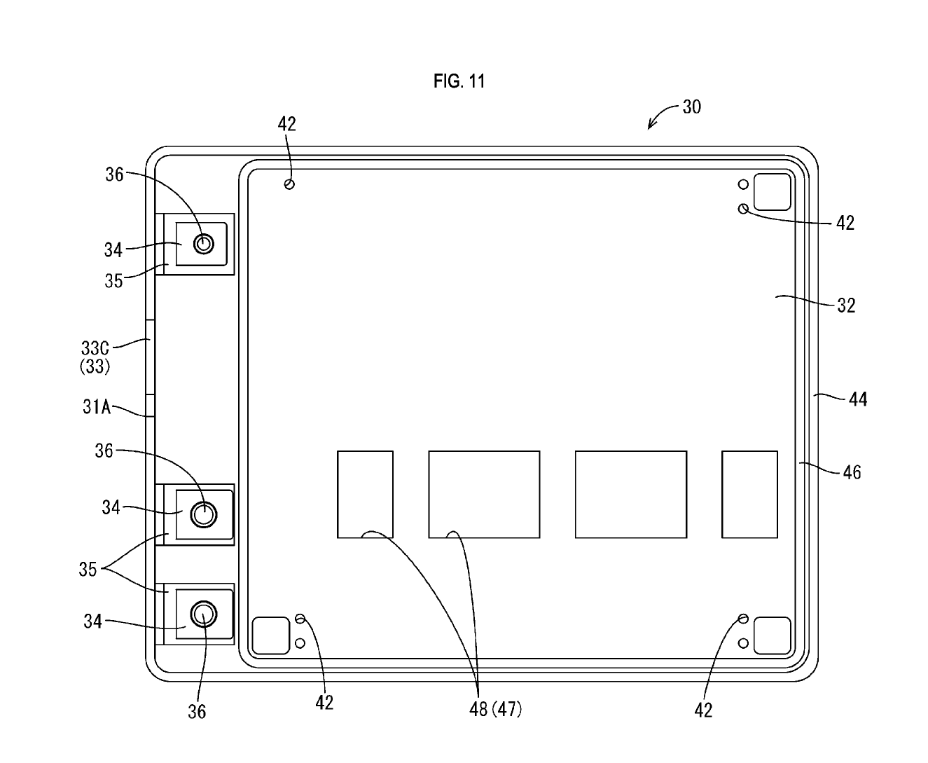

The circuit board 11 that is laid on the heatsink 20 via the insulation sheet is accommodated in the case 30 (see FIGS. 1 and 4). The case 30 is made of a synthetic resin, and has, as shown in FIGS. 11 to 15, the shape of a shallow dish in which a substantially rectangular frame 31 (an example of a frame body) that encloses the periphery of the circuit board 11, and a board covering portion 32 that covers the entire mounting surface 11A of the circuit board 11 are integrally formed.

The case 30 has a connection region that extends along one of the four side walls constituting the frame 31 (namely front wall 31A on the left side of FIG. 11), the connection region being a region for connecting the circuit board 11 and not-shown external terminals.

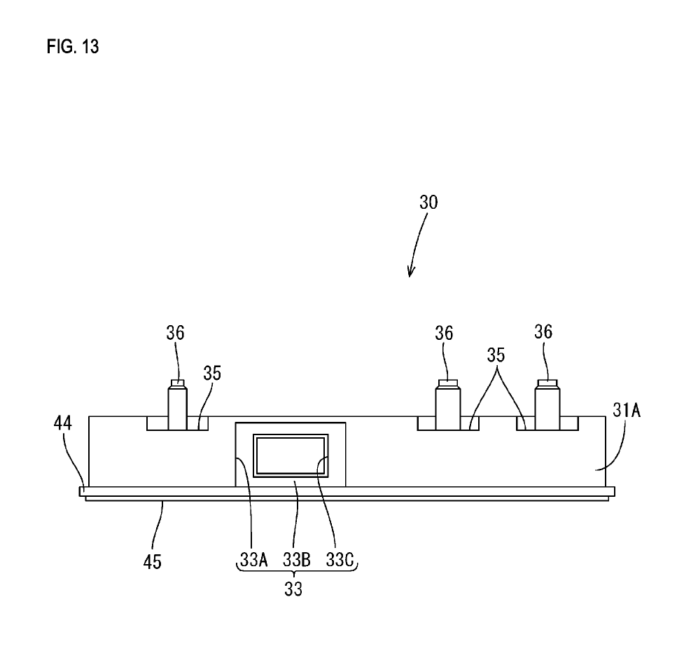

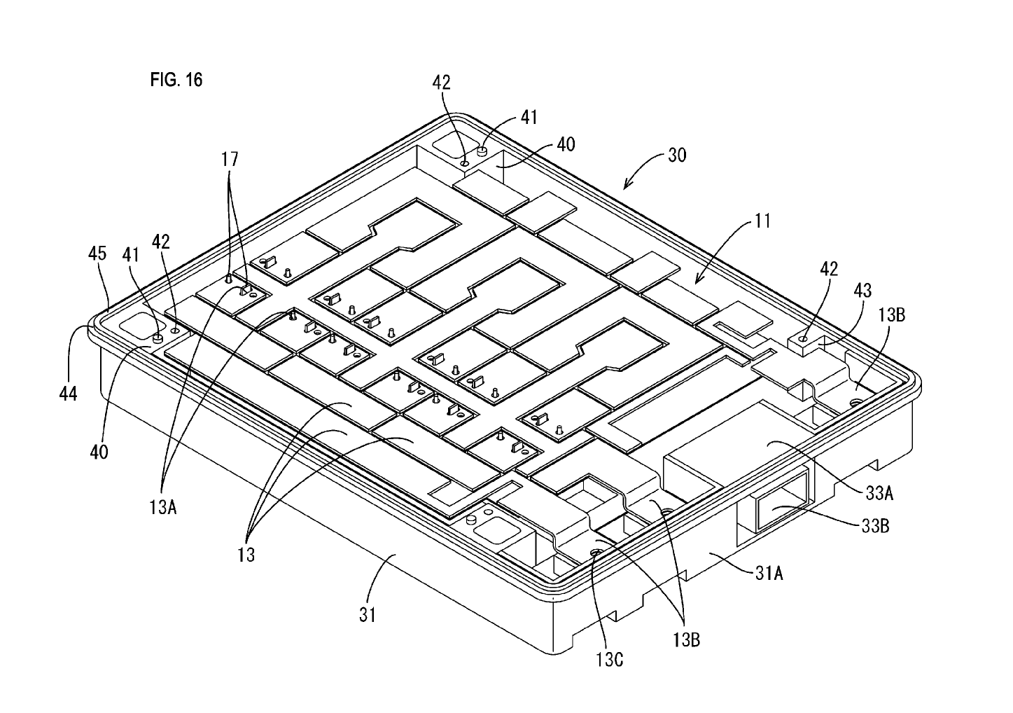

Specifically, as shown in FIGS. 13 and 15, the case 30 is open to the outside in the vicinity of the center, in the left-right direction, of the front wall 31A, and has a rectangular tubular connector hood 33 that extends inward into the frame 31 toward the opposite side wall (side wall on the rear side). The connector hood 33 is constituted by: an outer hood portion 33A that is contiguous from the front wall 31A and extends toward the rear side; and an inner hood portion 33C that is connected to the rear end of the outer hood portion 33A via a connection portion 33B and extends frontward inside the outer hood portion 33A. The front end of the inner hood portion 33C protrudes slightly frontward from the front wall 31A.

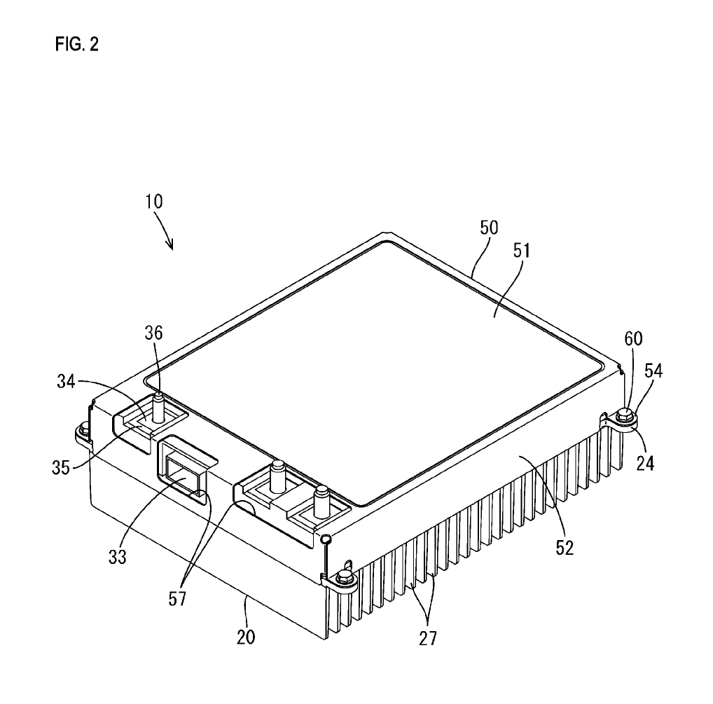

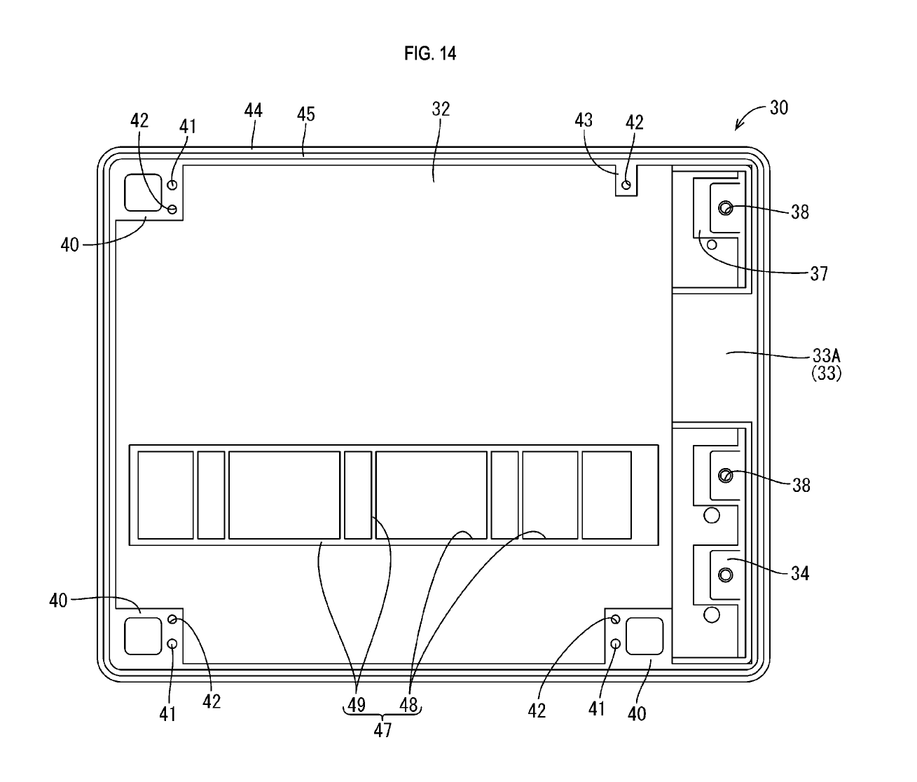

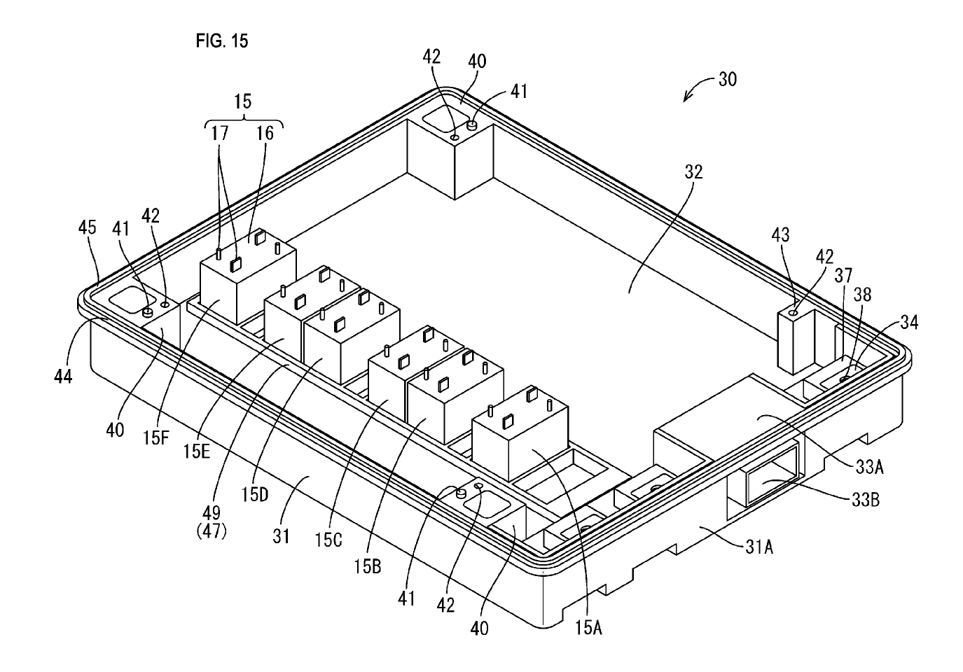

Furthermore, on both sides of this connector hood 33 in the left-right direction, three connection terminals 34 for connecting not-shown external terminals and the three external connection busbars 13B that extend from the edge of the circuit board 11 are provided. The connection terminals 34 are exposed on outer terminal blocks 35 (see FIGS. 2 and 11) provided on the outer side of the case 30, and on inner terminal blocks 37 (see FIGS. 14 and 15) provided on the inner side of the case 30, and are formed integrally with the terminal blocks 35 and 37.

Note that each outer terminal block 35 is provided with a round bar-like guide portion 36 for positioning an external terminal, the guide portion 36 extending upward. Furthermore, each inner terminal block 37 is provided with a bolt hole 38 for receiving a bolt (not shown) for fastening together and connecting the connection terminal 34 and the external connection busbar 13B.

As shown in FIGS. 14 to 17, the board covering portion 32 has, at three of the four corners of its region apart from the above-described connection region, rectangular tubular portions 40 that extend to the lower edge of the frame 31, and are formed integrally with the frame 31. Each rectangular tubular portion 40 has, on its lower surface, a pair of a case-side positioning portion 41 that is fitted into the heatsink-side positioning hole 21 of the heatsink 20, and a case-side fixation hole 42 that overlaps the heatsink-side first fixation hole 22. The case-side positioning portion 41 and the case-side fixation hole 42 are lined up in the left-right direction (up-down direction of FIG. 14).

On the other hand, in the vicinity of the one of the four corners of the region apart from the above-described connection region in which no rectangular tubular portion 40 is provided, the board covering portion 32 has a rectangular column portion 43 that extends to the lower edge of the frame 31, and is formed integrally with the frame 31. The lower surface of the rectangular column portion 43 is provided with a case-side fixation hole 42 that is provided alone, and overlaps the above-described heatsink-side first fixation hole 22A that is provided alone.

Furthermore, a flange portion 44 that protrudes outward is provided at the lower edge of the frame 31, and the case-side rib 45 that extends in an annular shape protrudes downward from the center, in the width direction, of the flange portion 44. The case-side rib 45 is configured to be fitted into the heatsink-side grove 26 (see FIGS. 4 and 15).

Furthermore, the upper surface of the board covering portion 32 is provided with, at the edge of its region apart from the above-described connection region, a case-side groove 46 that is recessed downward and extends annularly. A cover-side rib 56 of the later-described shield cover 50 is configured to be fitted into the case-side groove 46.

The board covering portion 32 of the case 30 of the present embodiment is provided with, at the positions that correspond to the coils 15 in a state in which the circuit board 11 is accommodated in the case 30, retaining portions 47 into which the upper end portions of the coils 15 are fitted.

More specifically, as shown in FIG. 4, the board covering portion 32 is provided with, at positions that correspond to the coils 15, a retaining hole 48 that is slightly larger than the outer shape of the upper end of the main portion 16 of the coil 15, and passes through the plate. Furthermore, the peripheral edges of these retaining holes 48 protrude toward the circuit board 11 side (downward) in the shape of a rib, and serve as retaining walls 49 that extend along the upper end portions of the outer surfaces (side surfaces) of the main portions 16 of the coils 15. That is, the retaining portions 47 are configured to include the retaining holes 48 and the retaining walls 49.

Note that in the present embodiment, six coils 15A, 15B, 15C, 15D, 15E, and 15F are arranged in a line, and thus the retaining walls 49 of adjacent retaining portions 47 extending in the front-rear direction are contiguous to each other in a straight line. Furthermore, out of the six coils arranged in a line, two pairs of coils other than the coils on both ends, namely, a pair of coils 15B and 15C, and a pair of coils 15D and 15E are arranged on the printed wiring board 12 so as to be close to each other with a small gap therebetween, and thus the retaining portions 47 for the closely arranged coils 15B and 15C, and the closely arranged coils 15D and 15E have no separation between them, and have such a size that two coils are arranged therein successively (see FIGS. 14 and 15). In other words, the two coils 15B and 15C, or the two coils 15D and 15E are fitted together into one retaining portion 47.

### Shield Cover 50

Furthermore, the surface (upper and outer surface) of the case 30 that is opposite to the side on which the circuit board 11 is arranged is covered with the shield cover 50 (an example of an outer case). The shield cover 50 is obtained by punching and bending, for example, a zinc steel plate (made of metal), and has the shape of a substantially rectangular shallow dish with a top panel portion 51 and four side walls 52 extending downward from the edge of the top panel portion 51. The size of the top panel portion 51 is set so as to be laid over the upper surface of the board covering portion 32 of the case 30.

A pair of long side walls 52 (left and right side walls 52) out of the four side walls 52 extend in the front-rear direction, and have, at both end portions, cover-side extension portions 54 that extend from the lower edge of the side walls 52 in the left-right direction (direction in which the short sides of the top panel portion 51 extend). The cover-side extension portions 54 are each provided with a cover-side fixation hole 55 that passes therethrough, and overlaps the heatsink-side second fixation hole 25.

As a result of these cover-side fixation holes 55 overlapping the heatsink-side second fixation holes 25, and bolts 60 being screwed therein, the heatsink 20 and the shield cover 50 are electrically connected to each other and are fixed into one piece (see FIGS. 2 and 4).

Furthermore, the lower surface of the top panel portion 51 is provided with, at the position that corresponds to the case-side groove 46 of the case 30, the cover-side rib 56, which is configured to be fitted into the case-side groove 46, is formed in an annular shape, and protrudes downward (see FIG. 4).

Furthermore, three hole portions 57 are provided at the positions that correspond to the outer terminal blocks 35 and the connector hood 33 of the case 30, the three hole portions 57 being open from the side wall 52 to the top panel portion 51, exposing the outer terminal blocks 35 and the connector hood 33 to the outside (see FIGS. 1 and 2).

### Method for Manufacturing Electrical Junction Box 10

The following will describe a method for manufacturing the electrical junction box 10 according to the present embodiment. First, a conductive circuit (not shown) is printed on the top side of an insulation board (the mounting surface 11A side of the circuit board 11) using printed wiring, and a plurality of busbars 13 are laid and adhered in a predetermined pattern to the back side thereof.

Then, as shown in FIG. 15, the case 30 is placed on a work table or the like in an upside-down state in which the back side of the case 30 faces upward, and the coils 15 are fitted into the retaining portions 47 in an upside-down state in which the lead terminals 17 of the coils 15 face upward. With this, six coils 15A to 15F are arranged at predetermined positions.

Then, the printed wiring board 12 on which the busbars 13 are laid is accommodated in the case 30 in an upside-down state in which the back sides of the busbars 13 face upward (see FIG. 16). Here, the printed wiring board 12 is accommodated in the case 30 so that the three external connection busbars 13B overlap the inner terminal blocks 37 of the case 30, and the lead terminals 17 of the coils 15 pass through the coil connecting through holes 14A of the printed wiring board 12 and the busbar-side through holes 13A of the busbars 13. Since, due to the retaining holes 48 and the retaining walls 49 (retaining portions 47) of the case 30, the plurality of coils 15A to 15F are arranged in advance at the predetermined positions in the case 30, that is, at predetermined mounting positions with respect to the printed wiring board 12, the lead terminals 17 of the coils 15 are passed through the coil connecting through holes 14A of the printed wiring board 12 and the busbar-side through holes 13A of the busbars 13 with accuracy.

Then, bolts (not shown) are screwed in the bolt holes 13C of the external connection busbars 13B and the bolt holes 38 of the inner terminal blocks 37 to electrically connect the external connection busbars 13B and the connection terminals 34 to each other, and solder (not shown) is applied to the vicinity of the busbar-side through holes 13A of the busbars 13, that is, the portions through which the lead terminals 17 are passed to electrically connect the busbars 13 and the lead terminals 17 to each other. Accordingly, a state is obtained in which the circuit board 11 in which the coils 15 are mounted on the printed wiring board 12 is accommodated in the case 30, and is held and fixed to the predetermined position in the case 30, and the circuit board 11 is electrically connected to the connection terminals 34 of the case 30.

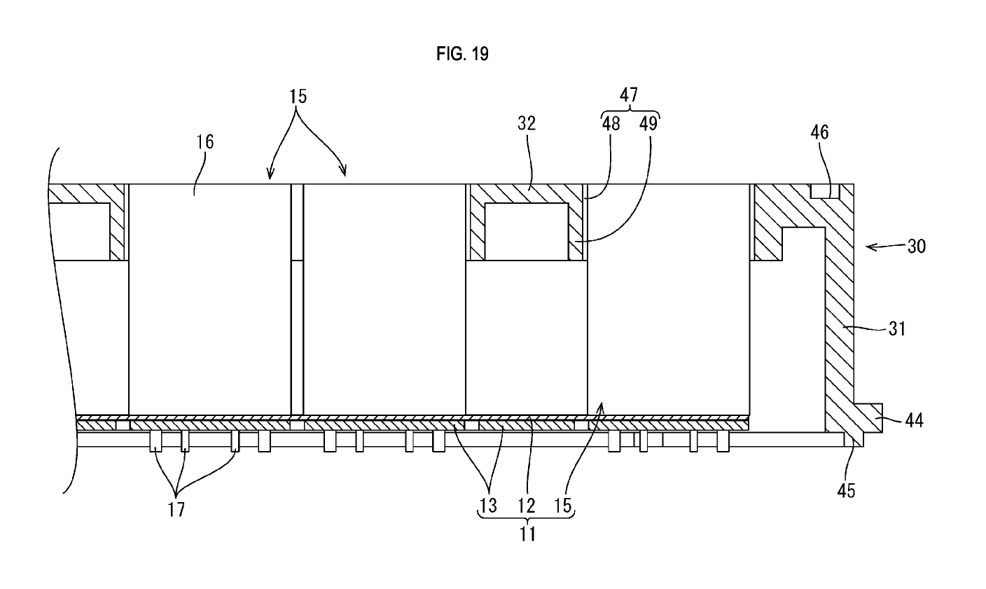

When the circuit board 11 and case 30 that have been formed as one piece in this state are turned upside down to be in the proper orientation, as shown in FIG. 19, the upper surfaces of the main portions 16 of the coils 15 and the upper surface of the board covering portion 32 of the case 30 are substantially coplanar. In other words, the upper surface of the board covering portion 32 is set in advance to be located at the same height as the main portions 16 of the coils 15 in the state in which the circuit board 11 is accommodated in the case 30. Note that “the same height” may include minor differences.

Then, the circuit board 11 and the case 30 that have been formed as one piece are placed at predetermined positions on the heatsink 20, that is, the positions at which the case 30 covers the entire upper surface of the heatsink 20. Note that at this time, the not-shown insulation sheet is arranged in advance at the position on the upper surface of the heatsink 20 at which the circuit board 11 is to be arranged. Accordingly, the case-side positioning portions 41 of the case 30 are fitted into the heatsink-side positioning holes 21 of the heatsink 20, and the case-side fixation holes 42 are arranged overlapping the heatsink-side first fixation holes 22. Furthermore, the case-side rib 45 is fitted into the heatsink-side grove 26. With this, the case 30 and the heatsink 20 are positioned relatively to each other. At the same time, the circuit board 11 that is held and fixed at the predetermined position on the case 30, and the heatsink 20 are positioned relatively to each other (see FIG. 10).

Note that here, as described above, the heatsink-side first fixation hole 22A provided alone is located displaced in position so that no case-side positioning portion 41 is fitted by mistake into the heatsink-side first fixation hole 22A, even if the case 30 is attempted to be attached to the heatsink 20 in a wrong direction while being rotated in the front-rear direction. Therefore, it is possible to detect when the case 30 is not attached to the heatsink 20 in the proper orientation.

Furthermore, when the circuit board 11 and the case 30 are arranged at the predetermined positions on the heatsink 20, then the lead terminals 17 of the coils 15 mounted on the circuit board 11 protrude from the lower surface of the circuit board 11. Since the escape recesses 23 are provided at the positions on the heatsink 20 at which the coils 15 are arranged, the lead terminals 17 are accommodated in the escape recesses 23 without interfering with the heatsink 20 (see FIG. 4).

Then, fastening members such as, for example, screw members are screwed from the lower surface side of the heatsink 20 into the heatsink-side first fixation holes 22 and the case-side fixation holes 42 that overlap and are in communication with each other, so that the heatsink 20 and the case 30 are fixed with respect to each other. Accordingly, a state is obtained in which the circuit board 11 that is held at the predetermined position in the case 30, and the heatsink 20 are indirectly fixed to each other.

Then, the shield cover 50 is laid over the case 30 from above to cover the case 30. Accordingly, the cover-side rib 56 is fitted into the case-side groove 46, and the cover-side fixation holes 55 overlap the heatsink-side second fixation holes 25. Then, the bolts 60 are inserted and screwed into the cover-side fixation holes 55 and the heatsink-side second fixation holes 25, so that the shield cover 50 and the heatsink 20 are fixed with respect to each other.

In this state, as shown in FIG. 2, the connector hood 33 and the outer terminal blocks 35 are exposed from the hole portions 57 of the shield cover 50. Furthermore, as shown in FIG. 4, the top panel portion 51 of the shield cover 50 is arranged overlapping (in contact with) the board covering portion 32 of the case 30. In other words, the top panel portion 51 of the shield cover 50 is arranged overlapping (in contact with) the upper surfaces of the coils 15 that are exposed from the board covering portion 32. The electrical junction box 10 is thus complete.

### Functions and Effects of Present Embodiment

According to the electrical junction box 10 of the present embodiment, the coils 15 are prevented, in the vicinity of their upper ends, from moving in a direction parallel to the mounting surface 11A of the circuit board 11 due to the retaining holes 48 and the retaining walls 49 (retaining portion 47) provided in the board covering portion 32 of the case 30. Furthermore, since the top panel portion 51 of the shield cover 50 is arranged on the outer side of the case 30 while overlapping the board covering portion 32 of the case 30, the top panel portion 51 prevents the coils 15 from moving in a direction perpendicular to the mounting surface 11A of the circuit board. In other words, the coils 15 are retained by the retaining portion 47 and the shield cover 50 so as not to move on the circuit board 11, and are thus kept fixed to the circuit board 11. This eliminates the need to additionally set a region in which a fixing means for fixing the coils 15 to the printed wiring board 12 is to be provided. In other words, it is possible to downsize the circuit board 11, and thus the electrical junction box 10.

Furthermore, since the case 30 (board covering portion 32) that is provided with the retaining holes 48 and the retaining walls 49 (retaining portions 47) has the same function as that of a positioning device for use when the coils 15 are arranged on the printed wiring board 12, that is, since the retaining portions 47 can be used to position the coils 15 with respect to the printed wiring board 12, no positioning jig or dedicated device is needed. Thus, in manufacturing, it is possible to omit steps in which such a positioning jig or dedicated device is used. In other words, it is possible to reduce the manufacturing cost, and simplify the manufacturing method.

Furthermore, since each pair of adjacent coils 15B and 15C, and adjacent coils 15D and 15E is configured to be fitted into one retaining portion 47, it is possible to further downsize the electrical junction box 10 as a whole.

Moreover, since the top panel portion 51 of the shield cover 50 is arranged overlapping (in contact with) the upper surfaces of the coils 15 that are exposed from the board covering portion 32, heat generated in the coils 15 can immediately be transmitted to the shield cover 50, and can be discharged to the outside.

### Other Embodiments

The technique disclosed in the present description is not limited to the embodiments described above with reference to the drawings, and the technical scope may encompass, for example, the following embodiments.

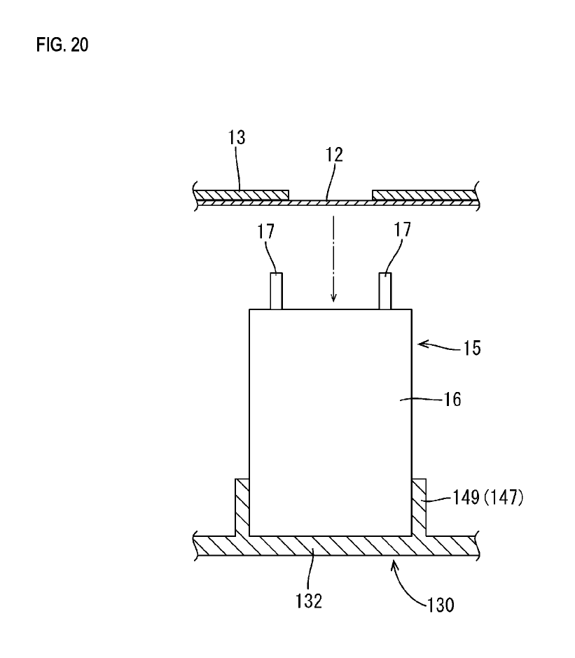

(1) In the foregoing embodiment, the retaining portions 47 are constituted by the retaining holes 48 and the retaining walls 49 of the board covering portion 32, but the present invention is not limited to the foregoing embodiment. A configuration is also possible in which, as shown in FIG. 20 for example, a covering portion 132 is not provided with a retaining hole but is provided only with retaining walls 149 that protrude toward the printed wiring board 12, and only the retaining walls 149 constitute a retaining portion 147.

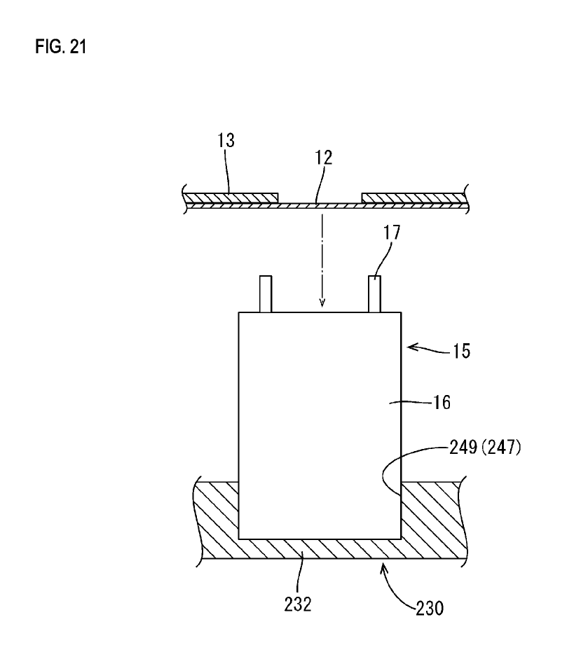

(2) Furthermore, the retaining walls do not necessarily protrude from the board covering portion, and a configuration is also possible in which, as shown in FIG. 21, a board covering portion 232 is formed with a large plate thickness, and a recessed inner surface that is recessed from the plate surface constitutes a retaining wall 249.

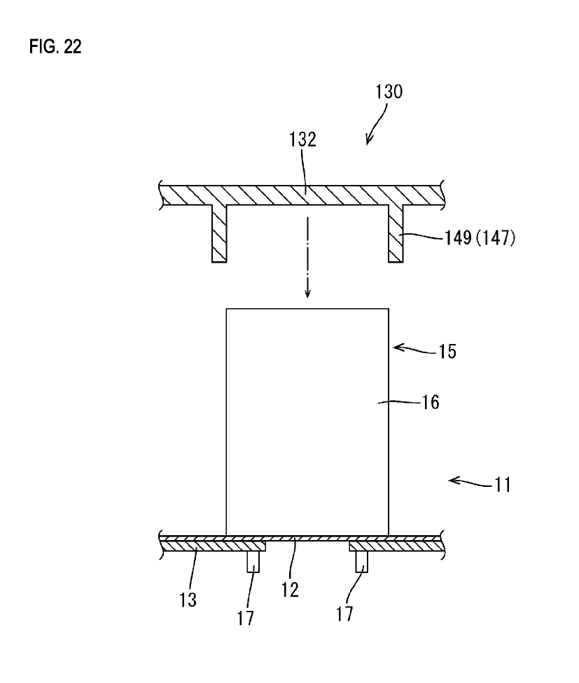

(3) In the foregoing embodiment, the manufacturing method is such that the coils 15 are fitted into the retaining portions 47 in the state in which the case 30 has been turned upside down, and then the printed wiring board 12 is attached from the side on which the lead terminals 17 of the coils 15 are located. But a configuration is also possible in which, as shown in FIG. 22 for example, a coil 15 is arranged at a predetermined position on the printed wiring board 12 and is connected by soldering to the printed wiring board 12, and then a case 130 is attached so that the coil 15 is fitted into a retaining portion 147.

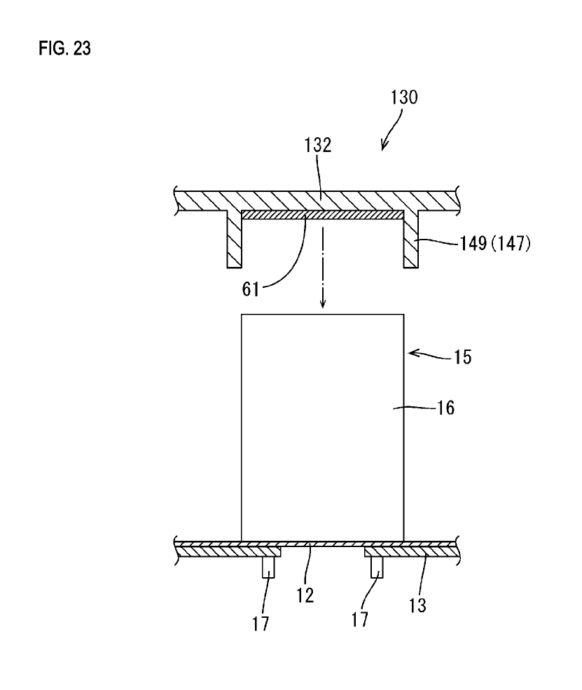

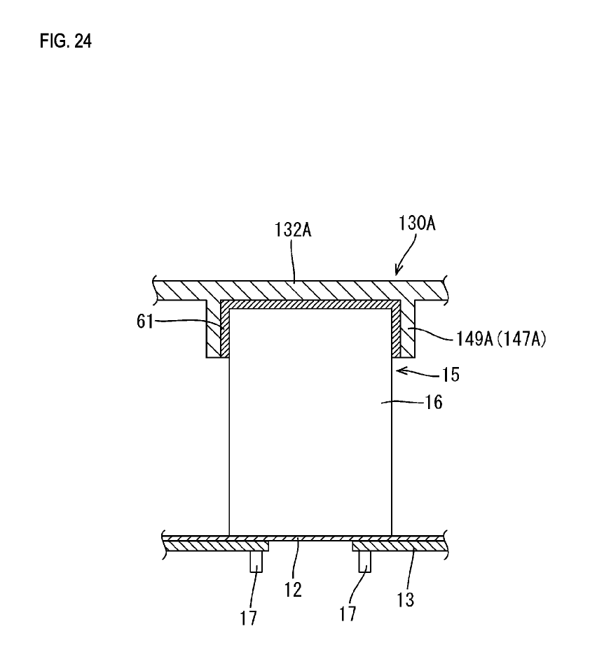

(4) As shown in FIG. 23 for example, an adhesive 61 may also be applied to a retaining portion 147 to fix a coil 15 in the retaining portion 147. When the coil 15 is fixed in the retaining portion using the adhesive 61 in this manner, it is also possible, as shown in FIG. 24, to set the inner size of a retaining portion 147A to be slightly larger than the outer size of the coil 15, so that the adhesive 61 is caused to spread to the sides of the coil 15. With this measure, the coil 15 is retained in the retaining portion 147A more reliably (see FIG. 24).

Furthermore, also when the retaining portion 47 has the retaining hole 48 as in the foregoing embodiment, an adhesive may also be applied to the inside or the peripheral edge portion of the retaining hole 48 to fix the coil 15.

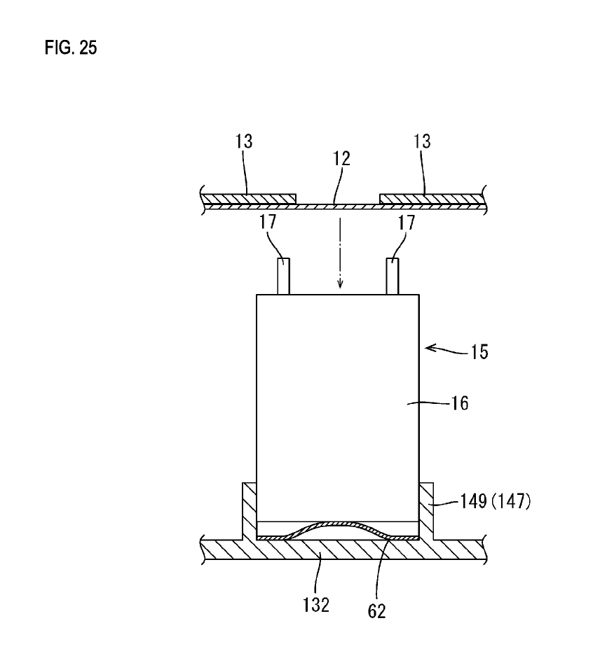

(5) Furthermore, as shown in FIG. 25 for example, a configuration is also possible in which an elastic means such as a spring member 62 is provided in a retaining portion 147 to bias a coil 15 to the printed wiring board 12 side. With this configuration, it is possible to retain the coil 15 on the printed wiring board 12 much more reliably. Specific examples of the spring member include a blade spring and a coil spring.

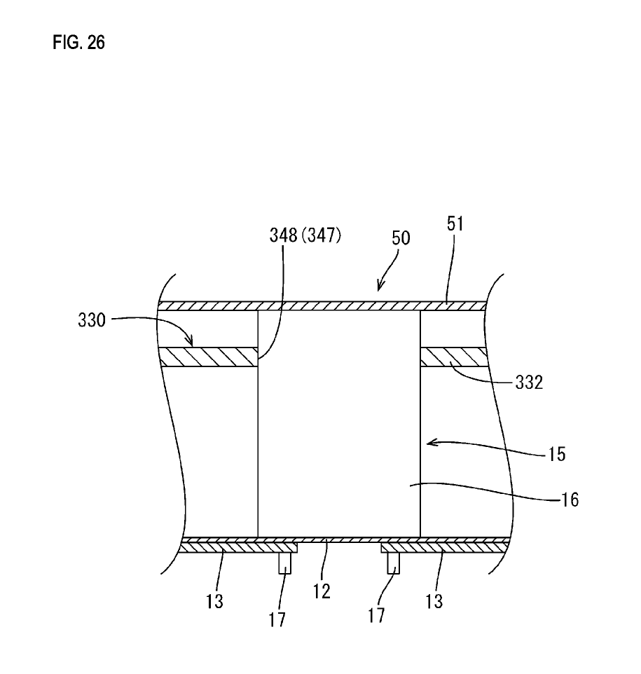

(6) As shown in FIG. 26 for example, a configuration is also possible in which a retaining portion 347 is not provided with a retaining wall but is provided only with a retaining hole 348 in a covering portion 332. In this configuration, it is also possible to retain a coil 15 on the circuit board 11 as a result of the main portion 16 of the coil 15 protruding further upward than the upper surface of the covering portion 332, and the top panel portion 51 of the shield cover 50 overlapping the upper surface of the main portion 16. Alternatively, a configuration is also possible in which the coil 15 is fixed to the retaining portion 347 as a result of an adhesive being applied to the vicinity of the retaining portion 347 (retaining hole 348).

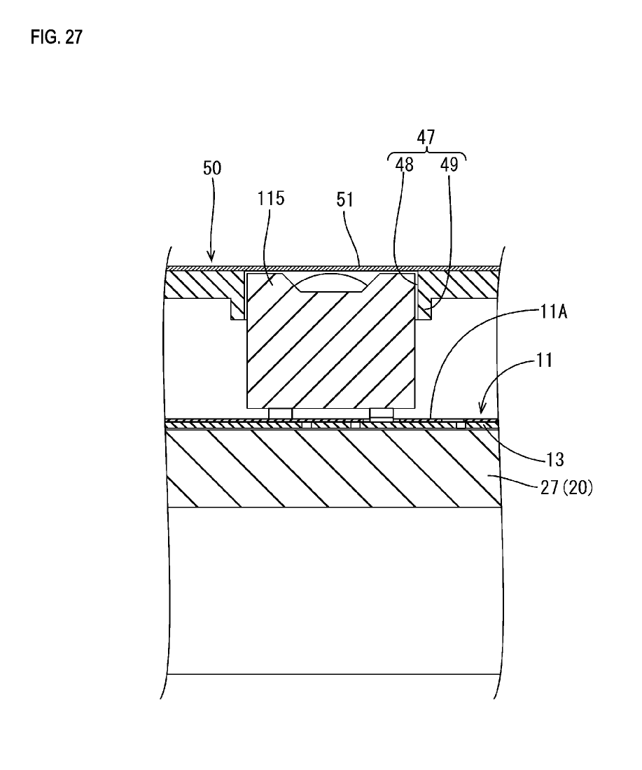

(7) In the foregoing embodiment, the lead-type coils 15 are exemplified as electronic components, but the electronic components are not limited to those of the foregoing embodiment. The technique disclosed in the present description is applicable to an electrical junction box in which, for example, a surface mounting-type coil 115 as shown in FIG. 27 is used.

(8) The board covering portion does not necessarily cover the entire circuit board 11, and it is sufficient for the board covering portion to be formed in a region that covers at least the coils 15.

(9) In the foregoing embodiment, the configuration is such that the case 30 is covered with the shield cover 50, but the shield cover 50 is not essential, and may also be omitted. Furthermore, a configuration is also possible in which, instead of the shield cover 50, an outer case made of a synthetic resin is provided.

(10) Furthermore, when the case 30 is covered with the shield cover 50 as in the foregoing embodiment, a thermally conductive adhesive may also be applied in advance to the exposed upper surfaces of the coils 15. According to this configuration, heat generated in the coils 15 is immediately transmitted to the shield cover 50, and is discharged to the outside, and thus an increase in the temperature of the electrical junction box 10 is further suppressed.

1. An electrical junction box comprising:
a circuit board that has a mounting surface on which an electronic component is mounted; and
a frame body in which the circuit board is accommodated,
wherein the frame body includes a board covering portion that covers at least a part of the electronic component on the mounting surface side,
the board covering portion is provided with a retaining portion that retains the electronic component, and
the retaining portion is a retaining wall that extends along an outer surface of the electronic component, and into which one end of the electronic component is fitted.

2. An electrical junction box comprising:
a circuit board that has a mounting surface on which an electronic component is mounted; and
a frame body in which the circuit board is accommodated,
wherein the frame body includes a board covering portion that covers at least a part of the electronic component on the mounting surface side,
the board covering portion is provided with a retaining portion that retains the electronic component, and
the retaining portion is a retaining hole that passes through the board covering portion.

3. The electrical junction box according to claim 2,
wherein the retaining hole has a retaining wall that extends along a side surface of the electronic component, and into which one end of the electronic component is fitted.

4. The electrical junction box according to claim 2, further comprising:
an outer case that covers the board covering portion from a side opposite to the side on which the circuit board is arranged while overlapping the board covering portion.

5. The electrical junction box according to claim 4,
wherein the electronic component and the outer case are adhered to each other by a thermally conductive adhesive.

6. The electrical junction box according to claim 1,
wherein the retaining portion is provided with a biasing means for biasing the electronic component to the mounting surface side.

7. The electrical junction box according to claim 6,
wherein the biasing means is a spring member.

8. The electrical junction box according to claim 1,
wherein the electronic component is fixed to the retaining portion with an adhesive.

9. The electrical junction box according to claim 1,
wherein a retaining portion into which a plurality of electronic components are together fitted is provided.
